(19) United States
(12) Patent Application Publication
(10) Pub. No.: US 2023/0084640 A1
(43) Pub. Date: Mar. 16, 2023

(54) ACOUSTIC RESONATOR PACKAGE

(71) Applicant: SAMSUNG ELECTRO-MECHANICS CO., LTD., Suwon-si (KR)

(72) Inventors: Nam Jung LEE, Suwon-si (KR); Tae Yoon KIM, Suwon-si (KR)

(73) Assignee: SAMSUNG ELECTRO-MECHANICS CO., LTD., Suwon-si (KR)

(21) Appl. No.: 17/684,732

(22) Filed: Mar. 2, 2022

(30) Foreign Application Priority Data
Sep. 10, 2021 (KR) 10-2021-0120923

(51) Int. Cl. H03H 9/10; H03H 9/17; H03H 3/02

(52) U.S. Cl. CPC H03H 9/105; H03H 9/172; H03H 3/02; H03H 2003/023

(57) ABSTRACT

An acoustic resonator package includes a substrate, a cap including a protrusion portion protruding toward the substrate, an acoustic resonator disposed between the substrate and the cap and including a first electrode, a piezoelectric layer, and a second electrode, a metal layer connected to one of the first electrode and the second electrode, and a conductive pad at least partially disposed between the protrusion portion and the metal layer and extending in a first direction different from a second direction in which the acoustic resonator faces the conductive pad.

### CROSS-REFERENCE TO RELATED APPLICATION(S)

This application claims the benefit under 35 USC 119(a) of Korean Patent Application No. 10-2021-0120923 filed on Sep. 10, 2021 in the Korean Intellectual Property Office, the entire disclosure of which is incorporated herein by reference for all purposes.

### BACKGROUND

### 1. FIELD

The following description relates to an acoustic resonator package.

### 2. DESCRIPTION OF BACKGROUND

With the rapid development of mobile communications devices, chemical and biological testing devices, and the like, demand for small and lightweight filters oscillators, resonant elements, and acoustic resonant mass sensors used in such devices has increased.

Acoustic resonators may be configured as a means for implementing such small and lightweight filters, oscillators, resonator elements, acoustic resonant mass sensors, and the like, and may have a very small size and good performance, compared to dielectric filters, metal cavity filters, and waveguides, and as such, acoustic resonators have been widely used in communications modules of modern mobile devices requiring good performance (e.g., small energy loss, a wide pass bandwidth).

A wavelength of radio frequency (RF) signals used in communications modules has been gradually shortened, and thus, a size of acoustic resonators or acoustic resonator packages including the acoustic resonator has also been gradually reduced. In addition, as the wavelength of the RF signals is shorter, more power is required in a transmission/reception process, and thus, importance of heat dissipation performance of the acoustic resonators or the acoustic resonator packages including the acoustic resonator has increased.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an acoustic resonator package includes: a substrate; a cap including a protrusion portion protruding toward the substrate; an acoustic resonator disposed between the substrate and the cap and including a first electrode, a piezoelectric layer, and a second electrode; a metal layer connected to one of the first electrode and the second electrode; and a conductive pad at least partially disposed between the protrusion portion and the metal layer and extending in a first direction different from a second direction in which the acoustic resonator faces the conductive pad.

A portion of the conductive pad disposed between the protrusion portion and the metal layer may be bent along an outer periphery of the acoustic resonator.

An extension length of a portion of the conductive pad disposed between the protrusion portion and the metal layer may be longer in the first direction than a width of the portion of the conductive pad disposed between the protrusion portion and the metal layer in the second direction.

A surface of the protrusion portion may contact the conductive pad and the surface may be uneven.

The acoustic resonator package may include a through-via defining an electrical path penetrating through the cap and electrically connected to the conductive pad.

The through-via may not overlap the protrusion portion in a direction in which the through-via penetrates through the cap.

The through-via may overlap the acoustic resonator in the direction in which the through-via penetrates through the cap, the second electrode may be disposed between the piezoelectric layer and the cap, and the metal layer may be connected to the second electrode.

The acoustic resonator package may include a bonding member that contacts the cap and is disposed between the substrate and the cap and surrounds the protrusion portion and the acoustic resonator, and the through-via may be electrically connected to the bonding member.

The through-via may include a plurality of through-vias, and the plurality of through-vias may include a first through-via disposed proximate to and electrically connected to the conductive pad and a second through-via disposed proximate to and electrically connected to the bonding member.

The acoustic resonator package may include a shield layer disposed on a surface of the cap facing the substrate and electrically connected to the conductive pad.

The acoustic resonator package may include a passive component disposed on a surface of the cap facing the substrate and electrically connected to the conductive pad.

The first electrode, the piezoelectric layer, and the second electrode may be stacked in a direction in which the substrate faces the cap.

In another general aspect, an acoustic resonator package includes: a substrate; a cap including a first protrusion protruding toward the substrate and a second protrusion protruding toward the substrate; a first acoustic resonator and a second acoustic resonator spaced apart from each other and disposed between the substrate and the cap, each of the first acoustic resonator and the second acoustic resonator comprising a first electrode, a piezoelectric layer, and a second electrode; a first metal layer connected between one of the first electrode and the second electrode of the first acoustic resonator and one of the first electrode and the second electrode of the second acoustic resonator; a second metal layer connected to an electrode that is not connected to the first metal layer, among the first electrode and the second electrode of the first acoustic resonator and the first electrode and the second electrode of the second acoustic resonator; a first conductive pad at least partially disposed between the first protrusion and the first metal layer; a second conductive pad at least partially disposed between the second protrusion and the second metal layer; and a passive component disposed on a surface of the cap facing the substrate and electrically connected between the first conductive pad and the second conductive pad.

A portion of the first conductive pad may extend in a first direction different from a second direction in which the first acoustic resonator faces the second acoustic resonator.

The acoustic resonator package may include a through-via defining an electrical path penetrating through the cap and electrically connected to the first conductive pad and the second conductive pad, and the through-via may not to overlap the first protrusion and the second protrusion in a direction in which the through-via penetrates through the cap.

The acoustic resonator package may include a third acoustic resonator electrically connected between a ground and one of the first metal layer and the second metal layer, and the passive component may include an inductor.

Other features and aspects will be apparent from the following detailed description, the drawings, and the claims.

### BRIEF DESCRIPTION OF DRAWINGS

FIG. 1 is a circuit diagram illustrating an acoustic resonator filter that may be included in an acoustic resonator package according to an example.

FIGS. 2A and 2B are a plan view and a side view illustrating a conductive pad of an acoustic resonator package according to an example.

FIG. 3 is a plan view illustrating a structure in which a conductive pad of an acoustic resonator package is bent along an outer periphery of an acoustic resonator according to an example.

FIGS. 4A and 4B are a plan view and a cross-sectional view illustrating an acoustic resonator package according to an example.

FIG. 5 is a side view illustrating a structure in which a conductive pad of an acoustic resonator package is connected to a second electrode of an acoustic resonator according to an example.

FIG. 6 is a side view illustrating a structure in which a conductive pad of an acoustic resonator package is electrically connected to a passive component according to an example.

FIGS. 7A and 7B are side views illustrating a structure in which passive components are electrically connected in parallel to an acoustic resonator in the acoustic resonator package according to an example.

FIGS. 8A and 8B are a side view and a perspective view illustrating a structure in which a conductive pad of an acoustic resonator package is electrically connected to a shield layer according to an example.

Throughout the drawings and the detailed description, the same reference numerals refer to the same elements. The drawings may not be to scale, and the relative size, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative sizes, proportions, and depiction of elements in the drawings may be exaggerated for clarity, illustration, and convenience.

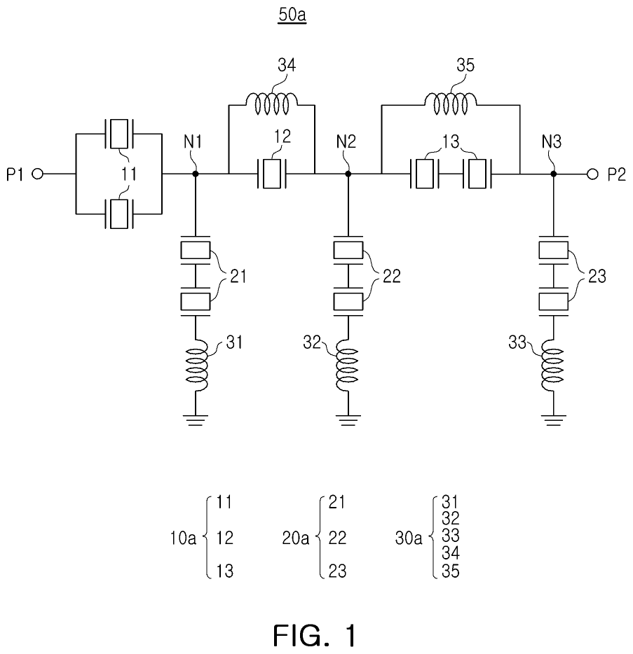

FIG. 1 is a circuit diagram illustrating an acoustic resonator filter that may be included in an acoustic resonator package according to an example.

Referring to FIG. 1, an acoustic resonator filter 50a may include a series portion 10a and a shunt portion 20a and may allow a radio frequency (RF) signal to pass through a portion between a first RF port P1 and a second RF port P2 or may block the RF signal.

The series portion 10a may include at least one series acoustic resonator 11, 12, and 13, and the shunt portion 20a may include at least one shunt acoustic resonator 21, 22, and 23.

A plurality of nodes N1, N2, and N3 between the at least one series acoustic resonator 11, 12, and 13, between the at least one shunt acoustic resonator 21, 22, and 23, and between the series portion 10a and the shunt portion 20a may be implemented as a metal layer. The metal layer may be formed of a material having a relatively low resistivity, such as gold (Au), gold-tin (Au·Sn) alloy, copper (Cu), copper-tin (Cu·Sn) alloy, aluminum (Al), aluminum alloy, and the like, but the material is not limited thereto.

Each of the at least one series acoustic resonator 11, 12, and 13 and the at least one shunt acoustic resonator 21, 22, and 23 may convert electrical energy of an RF signal into mechanical energy and may perform conversion inversely through a piezoelectric characteristic. As a frequency of an RF signal is closer to a resonant frequency of the acoustic resonator, an energy transfer rate between a plurality of electrodes may be significantly increased, and as a frequency of an RF signal is closer to an antiresonant frequency of the acoustic resonator, an energy transfer rate between a plurality of electrodes may be significantly lowered. The antiresonant frequency of the acoustic resonator may be higher than the resonant frequency of the acoustic resonator.

For example, each of the at least one series acoustic resonator 11, 12, and 13 and the at least one shunt acoustic resonator 21, 22, and 23 may be a film bulk acoustic resonator (FBAR), or a solidly mounted resonator (SMR)-type resonator.

At least one series acoustic resonator 11, 12, and 13 may be electrically connected between the first and second RF ports P1 and P2 in series. As the frequency of the RF signal is closer to the resonant frequency, a pass rate of the RF signal between the first and second RF ports P1 and P2 may be increased, and as the frequency of the RF signal is closer to the antiresonant frequency, the pass rate of the RF signal between the first and second RF ports P1 and P2 may be decreased.

The at least one shunt acoustic resonator 21, 22, and 23 may be electrically shunt-connected between the at least one series acoustic resonator 11, 12, and 13 and a ground GND. As the frequency of the RF signal is closer to the resonant frequency, a pass rate of the RF signal toward the ground GND may be increased, and as the frequency of the RF signal is closer to the antiresonant frequency, the pass rate of the RF signal toward the ground GND may be decreased.

A pass rate of the RF signal between the first and second RF ports P1 and P2 may be decreased as the pass rate of the RF signal toward the ground GND is higher, and may increased as the pass rate of the RF signal toward the ground GND is lower.

The pass rate of the RF signal between the first and second RF ports P1 and P2 may be lowered as the frequency of the RF signal is closer to the resonant frequency of the at least one shunt acoustic resonator 21, 22, and 23 or closer to the antiresonant frequency of the at least one series acoustic resonator 11, 12, and 13.

Since the antiresonant frequency is higher than the resonant frequency, the acoustic resonator filter 50a may have a pass bandwidth formed by the lowest frequency corresponding to the resonant frequency of the at least one shunt acoustic resonator 21, 22, and 23 and the highest frequency corresponding to the antiresonant frequency of the at least one series acoustic resonator 11, 12, and 13. Alternatively, the acoustic resonator filter 50a may have a stop bandwidth formed by the lowest frequency corresponding to the resonant frequency of the at least one series acoustic resonator 11, 12, and 13 and the highest frequency corresponding to the antiresonant frequency of the at least one shunt acoustic resonator 21, 22, and 23.

The pass bandwidth may be wider as a difference between the resonant frequency of the at least one shunt acoustic resonator 21, 22, and 23 and the antiresonant frequency of the at least one series acoustic resonator 11, 12, and 13 increases, and the stop bandwidth may be wider as the difference between the resonant frequency of the at least one series acoustic resonator 11, 12, and 13 and the antiresonant frequency of the at least one shunt acoustic resonator 21, 22 and 23 increases. However, if the difference is too large, the bandwidth may be split, and an insertion loss and/or return loss of the bandwidth may increase.

The bandwidth of the acoustic resonator filter 50a may be wide and may not be split or loss may be reduced when the resonant frequency of the at least one series acoustic resonator 11, 12, and 13 is suitably higher than the antiresonant frequency of the at least one shunt acoustic resonator 21, 22, and 23 or when the resonant frequency of the at least one shunt acoustic resonator 21, 22, and 23 is suitably higher than the antiresonant frequency of the at least one series acoustic resonator 11, 12, and 13.

In the acoustic resonator, the difference between the resonant frequency and the antiresonant frequency may be determined based on an electromechanical coupling factor kt², which is a physical characteristic of the acoustic resonator, and kt² may be determined based on a size, thickness, and shape of the acoustic resonator.

Depending on the design, the acoustic resonator filter 50a may have a frequency characteristic according to kt² of some acoustic resonators adjusted by including a passive component 30a. Accordingly, the principles for optimizing the frequency characteristics of the acoustic resonator filter 50a may be further diversified, so the filter performance (e.g., bandwidth, in-band loss, end-of-band attenuation characteristics, and the like) of the acoustic resonator filter 50a may be improved more efficiently.

For example, the passive component 30a may include at least one shunt inductor 31, 32, and 33 electrically connected in series between the plurality of nodes N1, N2, and N3 and the ground, and since the at least one shunt inductor 31, 32, and 33 may lower the resonant frequency without substantially affecting the antiresonant frequency of the at least one shunt acoustic resonator 21, 22, and 23, the at least one shunt inductor 31, 32, and 33 may play a part in the kt²-adjusted frequency characteristic.

For example, the passive component 30a may include at least one series inductor 34 and 35 electrically connected in parallel to the at least one series acoustic resonator 11, 12, and 13. The at least one series inductor 34 and 35 may lower the resonant frequency without substantially affecting the antiresonant frequency of the at least one series acoustic resonator 11, 12, and 13, so that the at least one series inductor 34 and 35 may play a part in the kt²-adjusted frequency characteristic.

Since the bandwidth of the acoustic resonator filter 50a may have a characteristic proportional to the overall frequency of the bandwidth, the bandwidth may be wider as the overall frequency of the bandwidth increases.

However, as the overall frequency of the bandwidth increases, the wavelength of the RF signal passing through the acoustic resonator filter 50a may be reduced. As the wavelength of the RF signal is reduced, energy attenuation compared to a transmission/reception distance in a remote transmission/reception process at the antenna may increase.

That is, as the overall frequency of the bandwidth of the acoustic resonator filter 50a increases, the RF signal passing through the acoustic resonator filter 50a may require greater power in consideration of energy attenuation in the remote transmission/reception process.

As the power of the RF signal passing through the acoustic resonator filter 50a increases, heating of each of the at least one shunt acoustic resonator 21, 22, and 23 and the at least one series acoustic resonator 11, 12, and 13 according to a piezoelectric operation and the possibility of damage due to heating may increase.

When each of the at least one shunt acoustic resonator 21, 22, and 23 and the at least one series acoustic resonator 11, 12, and 13 has a large size or is divided into a plurality of acoustic resonators connected to each other, the possibility of damage due to heating may be reduced but the overall size of the acoustic resonator filter 50a may be increased. That is, the possibility of damage due to heating of the acoustic resonator filter 50a and the overall size may be in a trade-off relationship with each other.

The acoustic resonator package according to the various examples of the present disclosure may increase heat dissipation efficiency of the acoustic resonator or may have a reduced size compared to the heat dissipation efficiency. Alternatively, since the acoustic resonator package according to an the various examples may efficiently use the passive component 30a, it may have improved filter performance compared to the overall size.

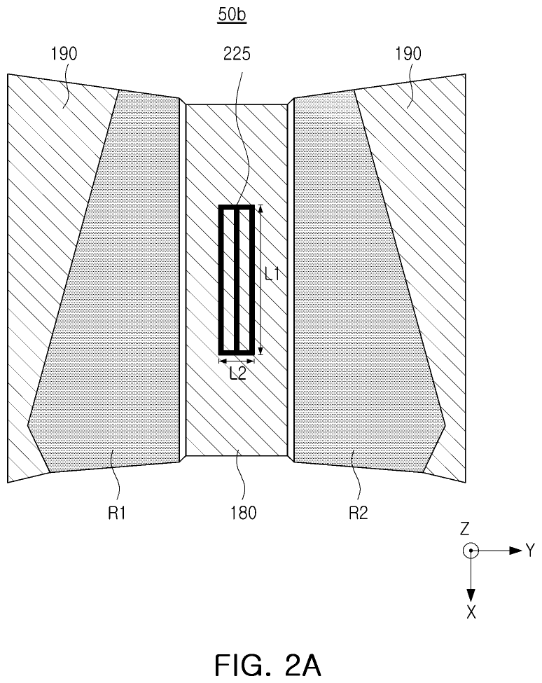

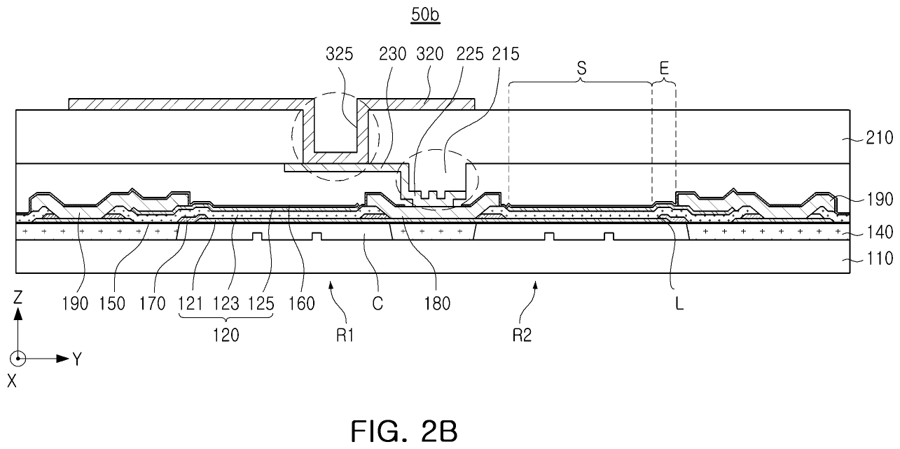

FIGS. 2A and 2B are a plan view and a side view illustrating a conductive pad of an acoustic resonator package according to an example.

Referring to FIGS. 2A and 2B, an acoustic resonator package 50b may include a substrate 110, a cap 210, at least one acoustic resonator R1 and R2, at least one metal layer 180 and 190, and a conductive pad 230, and at least one of the acoustic resonators R1 and R2 may be implemented as a bulk acoustic resonator.

The substrate 110 may be a silicon substrate. For example, a silicon wafer or a silicon on insulator (SOI) type substrate may be used as the substrate 110. An insulating layer may be provided on an upper surface of the substrate 110 to electrically isolate the substrate 110 and a resonant portion 120. The insulating layer may prevent the substrate 110 from being etched by an etching gas when a cavity C is formed during a manufacturing process of the acoustic resonator. In this case, the insulating layer may be formed of at least one of silicon dioxide (SiO₂), silicon nitride (Si₃N₄), aluminum oxide (Al₂O₃), and aluminum nitride (AlN), and may be formed through any one of processes among chemical vapor deposition, RF magnetron sputtering, and evaporation.

A support layer 140 may be formed on the insulating layer, and the support layer 140 may be disposed near a cavity C and an etch stop portion to surround the cavity C and the etch stop portion. The cavity C may be formed as an empty space and may be formed by removing a portion of a sacrificial layer formed in the process of preparing the support layer 140, and the support layer 140 may be formed as a remaining portion of the sacrificial layer. For the support layer 140, a material such as polysilicon or amorphous silicon that is easy to etch may be used. However, the material is not limited thereto. The etch stop portion may be disposed along a boundary of the cavity C. The etch stop portion may be provided to prevent etching from proceeding beyond the cavity region during the process of forming the cavity C.

A membrane layer 150 may be formed on the support layer 140 and form an upper surface of the cavity C. Therefore, the membrane layer 150 may also be formed of a material that is not easily removed in the process of forming the cavity C. For example, when a halide-based etching gas such as fluorine (F) or chlorine (CI) is used to remove a portion (e.g., a cavity region) of the support layer 140, the membrane layer 150 is formed with the etching gas and it may be made of a material with low reactivity. In this case, the membrane layer 150 may include at least one of silicon dioxide (SiO₂) and silicon nitride (Si₃N₄). In addition, the membrane layer 150 includes magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃).), titanium oxide (TiO₂), zinc oxide (ZnO), or made of a dielectric layer containing at least one material, aluminum (Al), nickel (Ni), chromium (Cr), platinum (Pt), It may be formed of a metal layer containing at least one of gallium (Ga) and hafnium (Hf). However, the configuration is not limited thereto.

The resonant portion 120 includes a first electrode 121, a piezoelectric layer 123, and a second electrode 125. In the resonance portion 120, the first electrode 121, the piezoelectric layer 123, and the second electrode 125 are sequentially stacked from the bottom (from the substrate 110 side). Accordingly, in the resonant portion 120, the piezoelectric layer 123 may be disposed between the first electrode 121 and the second electrode 125. Since the resonant portion 120 is formed on the membrane layer 150, the membrane layer 150, the first electrode 121, the piezoelectric layer 123, and the second electrode 125 may be sequentially stacked on the substrate 110 to form the resonant portion 120. The resonant portion 120 may resonate the piezoelectric layer 123 according to a signal applied to the first electrode 121 and the second electrode 125 to generate a resonant frequency and an antiresonant frequency.

The resonant portion 120 may be divided into a central portion S in which the first electrode 121, the piezoelectric layer 123, and the second electrode 125 are substantially flatly stacked and an expansion portion E in which an insertion layer 170 is provided between the first electrode 121 and the piezoelectric layer 123. The central portion S is a region disposed at the center of the resonant portion 120 and the expansion portion E is a region disposed along a circumference of the central portion S. Therefore, the expansion portion E is a region extending outwardly from the central portion S and refers to a region formed in a continuous ring shape along the circumference of the central portion S. However, if necessary, a portion thereof may be formed in a discontinuous ring shape.

Accordingly, in a cross-section of the resonant portion 120 taken to cross the central portion S, the expansion portions E may be disposed at both ends of the central portion S. The insertion layer 170 may be disposed on both sides of the expansion portion E disposed at both ends of the central portion S.

The insertion layer 170 may have an inclined surface L having a thickness increasing away from the central portion S. In the expansion portion E, the piezoelectric layer 123 and the second electrode 125 are disposed on the insertion layer 170. Accordingly, the piezoelectric layer 123 and the second electrode 125 positioned in the expansion portion E may have inclined surfaces along a shape of the insertion layer 170.

The expansion portion E may be defined to be included in the resonant portion 120, and thus, resonance may also be made in the expansion portion E. However, the configuration is not limited thereto, and, resonance may not occur in the expansion portion E and may be made only in the central portion S.

The first electrode 121 and the second electrode 125 may be formed of a conductor, for example, gold, molybdenum, ruthenium, iridium, aluminum, platinum, titanium, tungsten, palladium, tantalum, chromium, nickel, or a metal including at least thereof, but is not limited thereto.

In the resonant portion 120, the first electrode 121 is formed to have an area larger than that of the second electrode 125, and a first metal layer 180 is disposed on an outer portion of the first electrode 121 on the first electrode 121. Accordingly, the first metal layer 180 may be disposed to be spaced apart from the second electrode 125 by a predetermined distance and may be disposed to surround the resonant portion 120. Since the first electrode 121 is disposed on the membrane layer 150, the first electrode 121 may be formed to be flat as a whole. Since the second electrode 125 is disposed on the piezoelectric layer 123, a bent portion may be formed corresponding to a shape of the piezoelectric layer 123. The second electrode 125 may be entirely disposed in the central portion S, and may be partially disposed in the expansion portion E. The first electrode 121 and/or the second electrode 125 may be used as any one of an input electrode and an output electrode for inputting and outputting an electrical signal such as a radio frequency (RF) signal.

As a material of the piezoelectric layer 123, zinc oxide (ZnO), aluminum nitride (AlN), doped aluminum nitride, lead zirconate titanate, quartz, and the like may be selectively used. The doped aluminum nitride may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). The alkaline earth metal may also include magnesium (Mg). The content of elements doped into aluminum nitride (AlN) may range from 0.1 to 30 at %. The piezoelectric layer may be used by doping aluminum nitride (AlN) with scandium (Sc). In this case, a piezoelectric constant may be increased to increase Kt2 of the acoustic resonator.

The insertion layer 170 may be disposed on a surface formed by the membrane layer 150, the first electrode 121, and the etch stop portion. Accordingly, the insertion layer 170 may be partially disposed within the resonant portion 120 and may be disposed between the first electrode 121 and the piezoelectric layer 123. The insertion layer 170 may be disposed in a region excluding the central portion S. For example, the insertion layer 170 may be disposed in the entire region excluding the central portion S on the substrate 110 or may be disposed in a partial region.

The insertion layer 170 may be formed of a dielectric such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), and the like, but may be formed of a material different from that of the piezoelectric layer 123. The insertion layer 170 may be formed of a metal material. When the acoustic resonator is used in 5G communication, a lot of heat may be generated in the resonant portion 120, and thus, it is necessary to smoothly dissipate heat generated in the resonant portion 120. To this end, the insertion layer 170 may be formed of an aluminum alloy material containing scandium (Sc).

The resonant portion 120 may be spaced apart from the substrate 110 through the cavity C formed as an empty space. The cavity C may be formed by removing a portion of the support layer 140 by supplying an etching gas (or an etching solution) to an inflow hole during a manufacturing process of the acoustic resonator. Accordingly, the cavity C may be formed as a space in which an upper surface (a ceiling surface) and a side surface (a wall surface) are configured by the membrane layer 150 and a bottom surface is formed by the substrate 110 or the insulating layer. The membrane layer 150 may be formed only on the upper surface (the ceiling surface) of the cavity C according to the order of the manufacturing method.

A protective layer 160 may be disposed on the surface of the at least one acoustic resonator R1 and R2 to protect the at least one acoustic resonator R1 and R2 from the outside. The protective layer 160 may be disposed on a surface formed by the second electrode 125 and a bent portion of the piezoelectric layer 123. The protective layer 160 may be partially removed for frequency control in a final process during the manufacturing process. For example, a thickness of the protective layer 160 may be adjusted through frequency trimming during the manufacturing process.

To this end, the protective layer 160 may include any one of silicon dioxide (SiO₂), silicon nitride (Si₃N₄), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), polycrystalline silicon (p-Si) suitable for frequency trimming, but is not limited thereto.

The first electrode 121 and the second electrode 125 may extend to an outer side of the resonant portion 120. The first metal layer 180 and the second metal layer 190 may be disposed on upper surfaces of the extension portions, respectively.

The first metal layer 180 and the second metal layer 190 may be formed of any one of gold (Au), gold-tin (Au·Sn) alloy, copper (Cu), copper-tin (Cu—Sn) alloy, aluminum (Al), and an aluminum alloy. The aluminum alloy may be an aluminum-germanium (Al·Ge) alloy or an aluminum-scandium (Al·Sc) alloy.

One of the first metal layer 180 and the second metal layer 190 may electrically connect the plurality of acoustic resonators R1 and R2, and the other of the first metal layer 180 and the second metal layer 190 may electrically connect one of the plurality of acoustic resonators R1 and R2 to an adjacent acoustic resonator or port (e.g., a first port, a second port, and a ground port). That is, the first metal layer 180 and the second metal layer 190 may function as a connection line on the substrate 110.

For example, at least a portion of the first and second metal layers 180 and 190 may contact the protective layer 160 and may be bonded to the first and second electrodes 121 and 125. For example, the first metal layer 180 may be disposed along a portion of the periphery of the resonant portion 120, the second metal layer 190 may be disposed along the other portion of the periphery of the resonance portion 120, and the first and second metal layers 180 and 190 may surround the resonant portion 120. However, the configuration is not limited thereto.

The cap 210 may be disposed to be upwardly spaced apart from the plurality of acoustic resonators R1 and R2, and may include a protruding portion 215 protruding toward the substrate 110. The plurality of acoustic resonators R1 and R2 may be accommodated by the cap 210. The cap 210 may be coupled to at least one of the substrate 110, the support layer 140, and the membrane layer 150, and may cut off an internal space accommodated by the cap 210 and the outside of the cap 210. For example, the cap 210 may have a cover shape including the internal space, may have a U shape in a horizontal direction, and may contain an insulating material such as glass or silicon.

When the cap 210 is coupled to a lower structure (e.g., at least one of the substrate 110, the support layer 140, and the membrane layer 150), the cap 210 may receive an external force from an upper side. In this case, the protruding portion 215 of the cap 210 may provide a coupling force between the lower structure and the cap 210.

The conductive pad 230 may be disposed on a surface (e.g., a lower surface) of the cap 210 facing the substrate 110, and at least a portion 225 of the conductive pad 230 may be connected between the protruding portion 215 and the first or second metal layers 180 and 190.

Accordingly, heat generated by at least one of the plurality of acoustic resonators R1 and R2 may be dissipated to the outside of the cap 210 through the first or second metal layers 180 and 190, the conductive pad 230, the protruding portion 215, and the cap 210.

Also, at least the portion 225 of the conductive pad 230 may extend in a direction (e.g., an X-direction) different from the direction (e.g., a Y-direction) facing one of the plurality of acoustic resonators R1 and R2. Alternatively, at least the portion 225 of the conductive pad 230 may extend in a direction (e.g., the X-direction) different from a direction (e.g., the Y-direction) in which the plurality of acoustic resonators R1 and R2 face each other.

Accordingly, since a width of a heat dissipation path between at least one of the plurality of acoustic resonators R1 and R2 and the cap 210 may be widened, heat generated by at least one of the plurality of acoustic resonators R1 and R2 may be efficiently dissipated to the outside of the cap 210.

The width of the heat dissipation path may be proportional to an extension length L1 of at least the portion 225 of the conductive pad 230, and the extension length L1 may be longer than a width L2 of the conductive pad 230. Accordingly, a distance between the plurality of acoustic resonators R1 and R2 may be shortened, and thus, at least the portion 225 of the conductive pad 230 may be advantageously used as a heat dissipation path for all of the plurality of acoustic resonators R1 and R2.

According to design, the acoustic resonator package 50b may further include a through-via 325 providing an electrical path penetrating through the cap 210 and electrically connected to the conductive pad 230. For example, a portion of the cap 210 may include a bored portion between upper and lower portions of the cap 210, and at least a portion of the through-via 325 may be disposed on a side surface of the bored portion.

Accordingly, at least one of the plurality of acoustic resonators R1 and R2 may be electrically connected to the outside of the cap 210. For example, the through-via 325 may be electrically connected to the outside (e.g., a PCB) through a conductive pattern 320 disposed on an upper surface of the cap 210.

The number of vertical connection paths (e.g., through-vias penetrating through the substrate 110) between at least one of the plurality of acoustic resonators R1 and R2 and the lower side of the substrate 110 may be reduced by the number of the through-vias 325 provided in the cap 210, and thus, the through-via 325 or a combination of the through-via 325 and the vertical connection path may increase the degree of freedom of the plurality of acoustic resonators R1 and R2 on the substrate 110 and the acoustic resonator package 50b may have a reduced size compared to performance.

For example, at least one of the conductive pad 230, the through-via 325, and the conductive pattern 320 may be formed by applying metal paste (a metal material that may be included in a metal layer) on a surface of the cap 210 or plating a surface of the cap 210 before the cap 210 is coupled to the lower structure.

For example, the through-via 325 may be disposed so as not to overlap the protruding portion 215 in a direction (e.g., the Z-direction) in which the through-via 325 penetrates through the cap 210. Accordingly, the size of the protruding portion 215 may be reduced by the size of the through-via 325, so that a structure in which at least the portion 225 of the conductive pad 230 extends in a direction (e.g., the X-direction) different from the direction (e.g., the Y-direction) in which at least the portion 225 faces one of the plurality of acoustic resonators R1 and R2 may be more easily implemented.

Due to the size reduction of the protruding portion 215, a force applied from an upper side of the cap 210 may be more concentrated in the protruding portion 215 when the cap 210 is bonded to the lower structure (e.g., at least one of the substrate 110, the support layer 140, and the membrane layer 150), thereby increasing a coupling force between the cap 210 and the lower structure.

For example, since the plurality of acoustic resonator packages may be cut and manufactured after the substrate and the cap are coupled in a wafer level package process, a force applied to one of the plurality of acoustic resonator packages may be reduced as a size of one of the plurality of acoustic resonator packages is reduced. Accordingly, the coupling force between the cap 210 and the lower structure may become more important as the size of the acoustic resonator package 50b is reduced, and the reduction in the size of the protruding portion 215 of the cap 210 may increase the coupling force.

For example, a lower surface of the protruding portion 215 of the cap 210 may be uneven. Accordingly, the protruding portion 215 may allow pressure to be more concentrated during a coupling process between the cap 210 and the lower structure thereof, and at least the portion 225 of the conductive pad 230 may be formed to be denser between the protruding portion 215 and the first or second metal layers 180 and 190. For example, the uneven form may be a tread shape with an angle between a concave portion and a convex portion.

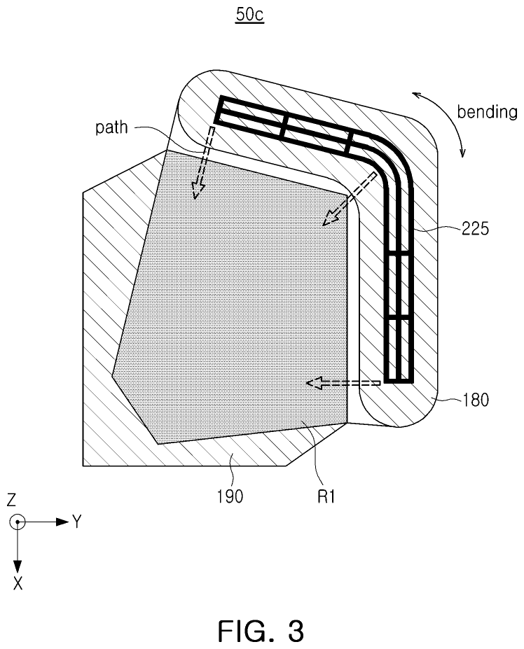

FIG. 3 is a plan view illustrating a structure in which a conductive pad of an acoustic resonator package is bent along an outer periphery of an acoustic resonator package according to an example.

Referring to FIG. 3, at least the portion 225 of the conductive pad of the acoustic resonator package 50c may be bent along an outer periphery of the acoustic resonator R1. Accordingly, since a width of the heat dissipation path of the acoustic resonator R1 may be further increased, heat generated in the acoustic resonator R1 may be efficiently dissipated externally.

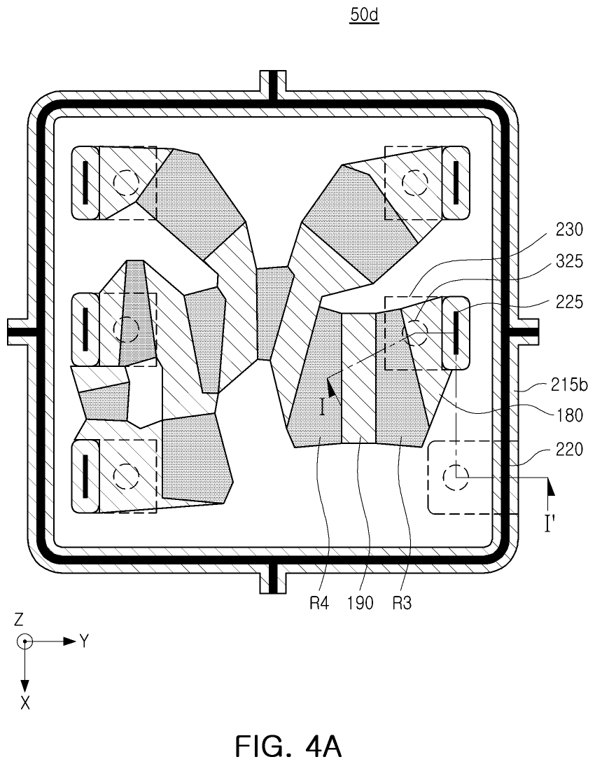

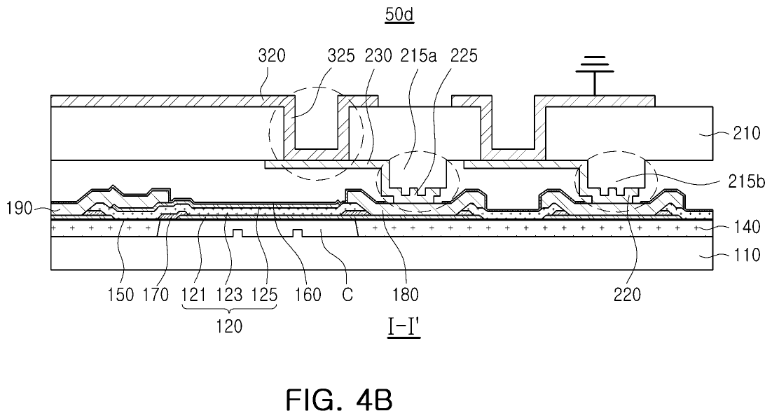

FIGS. 4A and 4B are a plan view and a cross-sectional view illustrating an acoustic resonator package according to an example.

Referring to FIGS. 4A and 4B, an acoustic resonator package 50d may further include a bonding member 220 in contact with the cap 210 between the substrate 110 and the cap 210 and surrounding a protruding portion 215a and acoustic resonators R3 and R4 in view of a protruding direction (e.g., the Z-direction) of the protruding portion 215a.

Accordingly, the cap 210 may be hermetically coupled to the lower structure (e.g., at least one of the substrate 110, the support layer 140, and the membrane layer 150) through the bonding member 220, and a space surrounded by the bonding member 220 may be disconnected from the outside of the cap 210.

For example, the bonding member 220 may have a structure in which a plurality of conductive rings are eutectic-bonded or an anodic bonding structure. For example, the bonding member 220 may be in contact with a lower surface of an outer protruding portion 215b of the cap 210.

Since the bonding member 220 may be electrically connected to the through-via 325 of the cap 210, the bonding member 220 may be provided with a ground from the outside. Accordingly, since a space allocated to provide a ground in the space surrounded by the bonding member 220 may be omitted, the space surrounded by the bonding member 220 may be smaller or may include more acoustic resonators R3 and R4.

For example, through-via 325 may include a plurality of through-vias, one of the plurality of through-vias may be electrically connected closer to the conductive pad 230 and the other may be electrically connected closer to the bonding member 220. Accordingly, the plurality of through-vias may perform different roles (e.g., a heat dissipation path, provision of a ground, a passive component connection path, and the like) for the acoustic resonators R3 and R4 and the bonding member 220.

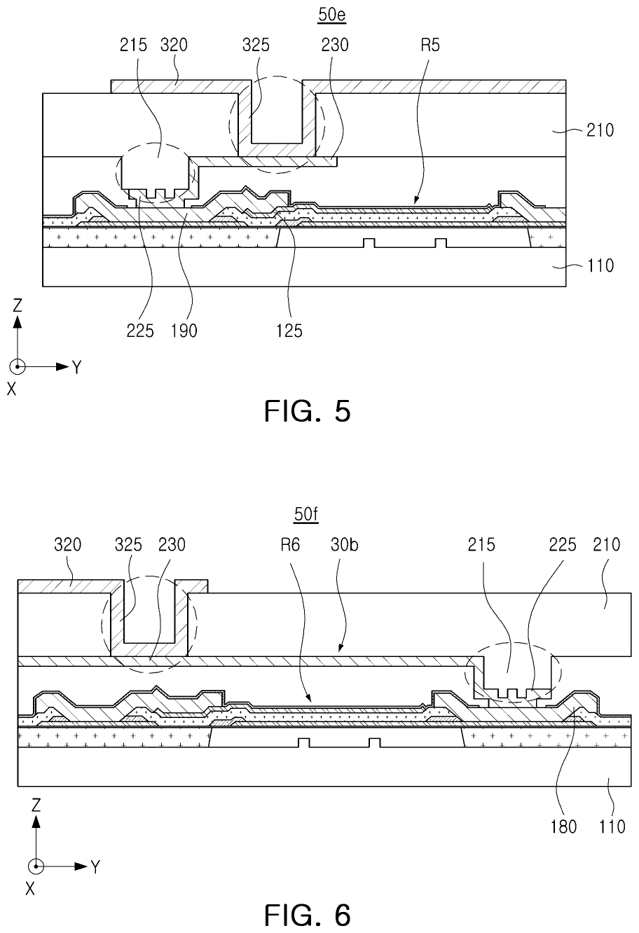

FIG. 5 is a side view illustrating a structure in which a conductive pad of an acoustic resonator package is connected to a second electrode of the acoustic resonator package according to an example.

Referring to FIG. 5, a through-via 325 of an acoustic resonator package 50e may be disposed to overlap an acoustic resonator R5 in a direction (e.g., the Z-direction) in which the through via 325 penetrates the cap 210. Accordingly, a size of the acoustic resonator package 50e may be more efficiently reduced by an overlapping area between the through-via 325 and the acoustic resonator R5.

In this example, the second electrode 125 may be disposed between the piezoelectric layer 123 and the cap 210, and a metal layer electrically connected to the through-via 325, among the first and second metal layers 180 and 190, may be connected to the second electrode 125. Accordingly, an occurrence of parasitic capacitance between the conductive pad 230 and the acoustic resonator R5 may be suppressed.

FIG. 6 is a side view illustrating a structure in which a conductive pad of an acoustic resonator package is electrically connected to a passive component according to an example.

Referring to FIG. 6, an acoustic resonator package 50f may further include a passive component 30b disposed on a surface (e.g., a lower surface) of the cap 210 facing the substrate 110 and electrically connected to the conductive pad 230. Accordingly, a size of the acoustic resonator package 50f may not increase even if the passive component 30b is used.

For example, an acoustic resonator R6 may be at least one shunt acoustic resonator 21, 22, and 23 illustrated in FIG. 1, and the passive component 30b may be at least one shunt inductor 31, 32, and 33 illustrated in FIG. 1 and may be electrically connected between the through-via 325 providing a ground and the acoustic resonator R6.

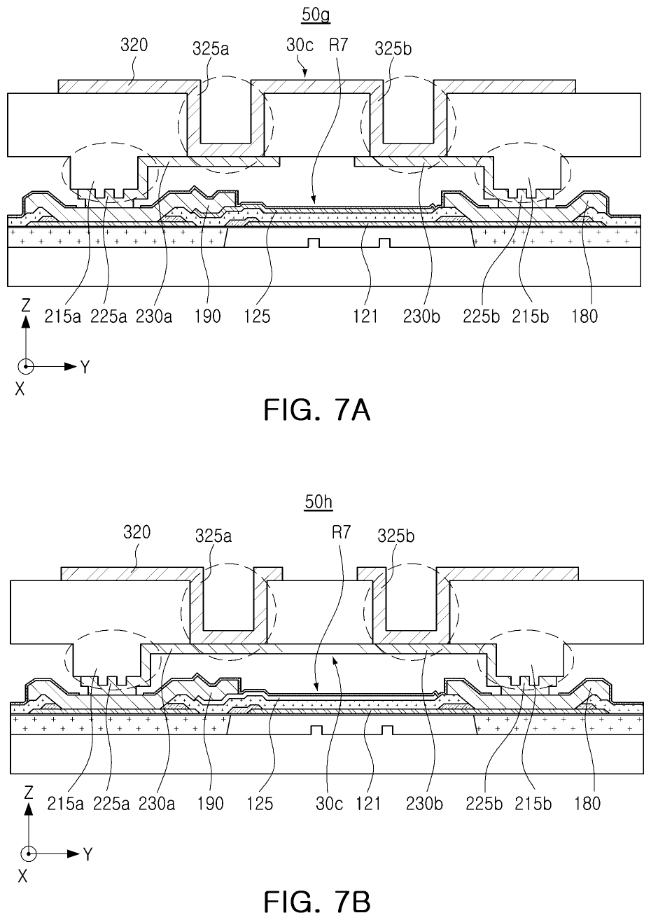

FIGS. 7A and 7B are side views illustrating a structure in which passive components are electrically connected in parallel to an acoustic resonator in the acoustic resonator package according to an example.

Referring to FIGS. 7A and 7B, the cap of the acoustic resonator packages 50g and 50h may include first and second protruding portions 215b and 215a protruding toward the substrate.

The first conductive pad 225b may be connected between the first protruding portion 215b and the first metal layer 180, and the second conductive pad 225a may be connected between the second protruding portion 215a and the second metal layer 190.

The first metal layer 180 may be electrically connected between a first acoustic resonator R7 and a right second acoustic resonator, and the second metal layer 190 may be electrically connected between the first acoustic resonator R7 and a left additional acoustic resonator or a port (e.g., a first port, a second port, and a ground port).

Referring to FIG. 7A, a passive component 30c may be electrically connected between a plurality of through-vias 325a and 325b, and the plurality of through-vias 325a and 325b may be electrically connected to the first and second conductive pads 225b and 225a, respectively. Referring to FIG. 7B, the passive component 30c may be electrically connected between the first and second conductive pads 225b and 225a.

Accordingly, the passive component 30c may be electrically connected to a first acoustic resonator R7 in parallel. For example, the first acoustic resonator R7 may be at least one series acoustic resonator 12 and 13 illustrated in FIG. 1, and the passive component 30c may be at least one series inductor 34 and 35 illustrated in FIG. 1. One of the second acoustic resonator and the additional acoustic resonator may be at least one series acoustic resonator 11, 12, and 13 illustrated in FIG. 1, and the other one may be at least one shunt acoustic resonator 21, 22, and 23 illustrated in FIG. 1. Depending on the design, the plurality of through-vias 325a and 325b may be omitted.

For example, the plurality of through-vias 325a and 325b may be disposed so as not to overlap the first and second protruding portions 215b and 215a in a direction (e.g., in the Z-direction) in which the plurality of through-vias 325a and 325b penetrate through the cap.

Accordingly, even when the passive component 30c electrically connected in parallel to the first acoustic resonator R7 is used, the first and second metal layers 180 and 190 may not increase a distance between the first acoustic resonator R7 and the adjacent acoustic resonator, and thus, the acoustic resonator packages 50g and 50h may efficiently use the passive component 30c and a size of the acoustic resonator packages 50g and 50h may be reduced compared to the performance.

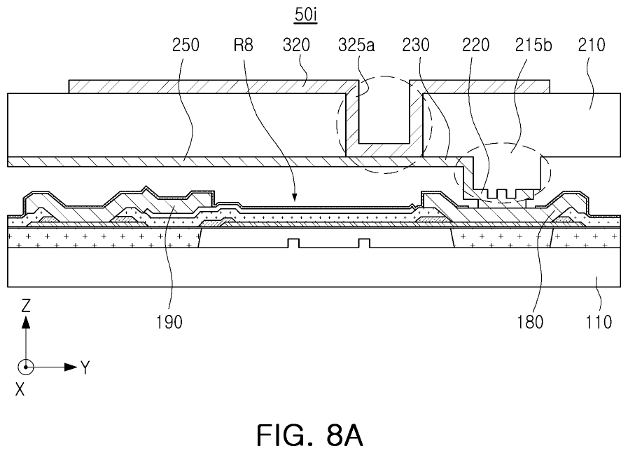

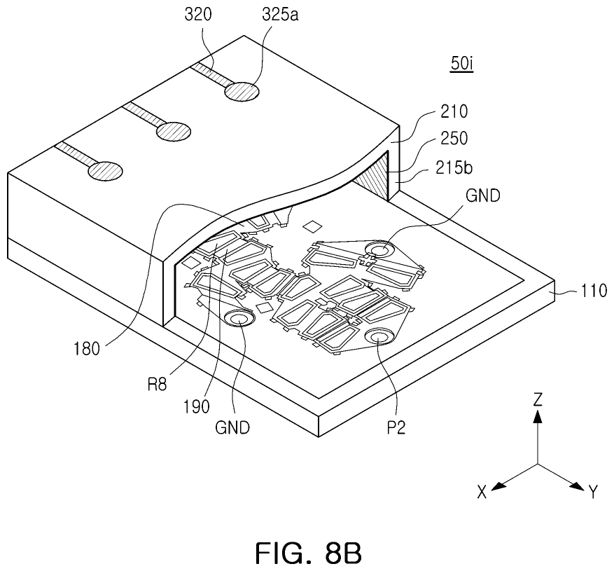

FIGS. 8A and 8B are a side view and a perspective view illustrating a structure in which a conductive pad of an acoustic resonator package is electrically connected to a shield layer according to an example.

Referring to FIGS. 8A and 8B, an acoustic resonator package 50i may further include a shield layer 250 disposed on a surface (e.g., a lower surface) of the cap 210 facing the substrate 110 and electrically connected to the conductive pad 230.

Since the shield layer 250 may electromagnetically cut off the space surrounded by the cap 210 and the outside of the cap 210, a plurality of acoustic resonators R8 may be protected from external electromagnetic noise.

For example, the shield layer 250 may be provided with a ground through the bonding member 220 or the through-via 325a. For example, the through-via 325a may be provided with external grounding (e.g., PCB) through the conductive pattern 320, and may be electrically connected to one of the first and second metal layers 180 and 190. One of the plurality of acoustic resonators R8 may be electrically connected between the first and second metal layers 180 and 190.

The plurality of acoustic resonators R8 may be electrically connected between a first port and a second port and may be electrically connected to a ground port GND. For example, the first port, the second port, and the ground port GND may be implemented as a vertical connection path penetrating through the substrate 110, and may be implemented as a structure penetrating through the cap 210, similar to the through-via 325a, according to the design.

As set forth above, the acoustic resonator package according to the various disclosed examples may increase heat dissipation efficiency of the acoustic resonator or have a reduced size compared to the heat dissipation efficiency. Furthermore, the acoustic resonator package according to the various disclosed examples may efficiently use the passive component, thus having improved filter performance, compared to the overall size thereof.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic resonator package comprising:
a substrate;
a cap comprising a protrusion portion protruding toward the substrate;
an acoustic resonator disposed between the substrate and the cap and comprising a first electrode, a piezoelectric layer, and a second electrode;
a metal layer connected to one of the first electrode and the second electrode; and
a conductive pad at least partially disposed between the protrusion portion and the metal layer and extending in a first direction different from a second direction in which the acoustic resonator faces the conductive pad.

2. The acoustic resonator package of claim 1, wherein a portion of the conductive pad disposed between the protrusion portion and the metal layer is bent along an outer periphery of the acoustic resonator.

3. The acoustic resonator package of claim 1, wherein an extension length of a portion of the conductive pad disposed between the protrusion portion and the metal layer is longer in the first direction than a width of the portion of the conductive pad disposed between the protrusion portion and the metal layer in the second direction.

4. The acoustic resonator package of claim 1, wherein a surface of the protrusion portion contacts the conductive pad and the surface is uneven.

5. The acoustic resonator package of claim 1, further comprising a through-via defining an electrical path penetrating through the cap and electrically connected to the conductive pad.

6. The acoustic resonator package of claim 5, wherein the through-via does not overlap the protrusion portion in a direction in which the through-via penetrates through the cap.

7. The acoustic resonator package of claim 6, wherein
the through-via overlaps the acoustic resonator in the direction in which the through-via penetrates through the cap,
the second electrode is disposed between the piezoelectric layer and the cap, and
the metal layer is connected to the second electrode.

8. The acoustic resonator package of claim 5, further comprising a bonding member that contacts the cap and is disposed between the substrate and the cap and surrounds the protrusion portion and the acoustic resonator,
wherein the through-via is electrically connected to the bonding member.

9. The acoustic resonator package of claim 8, wherein
the through-via comprises a plurality of through-vias, and
the plurality of through-vias comprises a first through-via disposed proximate to and electrically connected to the conductive pad and a second through-via disposed proximate to and electrically connected to the bonding member.

10. The acoustic resonator package of claim 1, further comprising a shield layer disposed on a surface of the cap facing the substrate and electrically connected to the conductive pad.

11. The acoustic resonator package of claim 1, further comprising a passive component disposed on a surface of the cap facing the substrate and electrically connected to the conductive pad.

12. The acoustic resonator package of claim 1, wherein the first electrode, the piezoelectric layer, and the second electrode are stacked in a direction in which the substrate faces the cap.

13. An acoustic resonator package comprising:
a substrate;
a cap comprising a first protrusion protruding toward the substrate and a second protrusion protruding toward the substrate;
a first acoustic resonator and a second acoustic resonator spaced apart from each other and disposed between the substrate and the cap, each of the first acoustic resonator and the second acoustic resonator comprising a first electrode, a piezoelectric layer, and a second electrode;
a first metal layer connected between one of the first electrode and the second electrode of the first acoustic resonator and one of the first electrode and the second electrode of the second acoustic resonator;
a second metal layer connected to an electrode that is not connected to the first metal layer, among the first electrode and the second electrode of the first acoustic resonator and the first electrode and the second electrode of the second acoustic resonator;
a first conductive pad at least partially disposed between the first protrusion and the first metal layer;
a second conductive pad at least partially disposed between the second protrusion and the second metal layer; and
a passive component disposed on a surface of the cap facing the substrate and electrically connected between the first conductive pad and the second conductive pad.

14. The acoustic resonator package of claim 13, wherein a portion of the first conductive pad extends in a first direction different from a second direction in which the first acoustic resonator faces the second acoustic resonator.

15. The acoustic resonator package of claim 13, further comprising:
a through-via defining an electrical path penetrating through the cap and electrically connected to the first conductive pad and the second conductive pad,
wherein the through-via does not to overlap the first protrusion and the second protrusion in a direction in which the through-via penetrates through the cap.

16. The acoustic resonator package of claim 13, further comprising a third acoustic resonator electrically connected between a ground and one of the first metal layer and the second metal layer,
wherein the passive component comprises an inductor.
